(19) United States
(12) Patent Application Publication
(10) Pub. No.: US 2019/0053406 A1
(43) Pub. Date: Feb. 14, 2019

(54) SEMICONDUCTOR DEVICE

(71) Applicant: SONY CORPORATION, TOKYO (JP)

(72) Inventor: HIROYUKI TEZUKA, TOKYO (JP)

(21) Appl. No.: 16/077,158

(22) PCT Filed: Nov. 14, 2016
(86) PCT No.: PCT/JP2016/083641

§ 371 Date: Aug. 10, 2018

(30) Foreign Application Priority Data
Feb. 29, 2016 (JP) 2016-036553

(51) Int. Cl. H05K 9/00; H01L 21/3205; H01L 21/768; H01L 21/822; H01L 23/522; H01L 25/065; H01L 27/146; H04N 5/369

(52) U.S. Cl. CPC H05K 9/0073; H01L 21/3205; H01L 21/768; H04N 5/369; H01L 23/522; H01L 25/065; H01L 27/146; H01L 21/822

(57) ABSTRACT

[Object] To reduce electromagnetic noise with ease in a semiconductor device provided with wiring serving as a source of noise. [Solution] The semiconductor device includes first and second substrates. In this semiconductor device, a plurality of first signal lines are wired in a predetermined direction on the first substrate. In addition, in a semiconductor device on which the plurality of first signal lines are wired in the predetermined direction, a second signal line, which produces a plurality of magnetic fields with mutually different directions in a region between two adjacent signal lines of the plurality of first signal lines, is wired on the second substrate.

### TECHNICAL FIELD

The present technology relates to semiconductor devices. In particular, the present technology relates to a semiconductor device provided with wiring that is likely to be a source of noise.

### BACKGROUND ART

It is known that electromagnetic noise is produced by a magnetic field from a source of noise in a typical semiconductor device until now. In one example, wiring such as a power line serving as a source of noise causes a magnetic field to be produced, causing electromagnetic noise in a circuit near the wiring. A semiconductor device is developed in which an electromagnetic shield is inserted between a source of noise and a circuit to be protected to reduce such electromagnetic noise (e.g., see Patent Literature 1).

### CITATION LIST

### Patent Literature

Patent Literature 1: JP 2005-005741A

### DISCLOSURE OF INVENTION

### Technical Problem

In the above-described technique in related art, however, the arrangement of the electromagnetic shield may cause a cost increase or restrictions on circuit design disadvantageously. In addition, in a case where a magnetic material is used as the electromagnetic shield, pollution in the factory due to the magnetic material may occur disadvantageously. In addition, the installation of the electromagnetic shield causes an increase in the size of a package in the semiconductor device disadvantageously. For these reasons, it is difficult to reduce electromagnetic noise.

The present technology is made in view of such a situation, and it is intended to reduce electromagnetic noise with ease in a semiconductor device provided with wiring serving as a source of noise.

### Solution to Problem

The present technology has been made to solve the above problem. According to the first aspect of the present disclosure, a semiconductor device includes: a first substrate having a plurality of first signal lines wired on the first substrate in a predetermined direction; and a second substrate having a second signal line wired on the second substrate, the second signal line being configured to produce a plurality of magnetic fields with mutually different directions in a region between two adjacent signal lines among the plurality of first signal lines. This leads to an effect that a plurality of magnetic fields with mutually different directions are produced in the region between two adjacent signal lines.

In addition, according to the first aspect, the plurality of first signal lines may be wired in parallel to each of two directions orthogonal to each other. This leads to an effect that a plurality of magnetic fields with mutually different directions are produced in the region between the signal lines wired in parallel to each of two directions orthogonal to each other.

In addition, according to the first aspect, the second signal line may be wired along a specific direction different from any of the two directions. This leads to an effect that a plurality of magnetic fields with mutually different directions are produced by the second signal line wired along the specific direction different from any of two directions.

In addition, according to the first aspect, the second signal line may have a part wired along the specific direction and a remaining part wired along at least one of the two directions. This leads to an effect that a plurality of magnetic fields with mutually different directions are produced by the second signal line having a part wired along the specific direction and the remaining part wired along at least one of two directions.

In addition, according to the first aspect, the second signal line may be wired along each of a plurality of directions different from any of the two directions. This leads to an effect that a plurality of magnetic fields with mutually different directions are produced by the second signal line wired along each of a plurality of directions different from any of two directions.

In addition, according to the first aspect, the second signal line may be wired along a path bending at a plurality of bending points. This leads to an effect that a plurality of magnetic fields with mutually different directions are produced by the second signal line wired along the path bending at a plurality of bending points.

In addition, according to the first aspect, the second substrate may have a predetermined number of the second signal lines wired on the second substrate, and an electric current may flow through the two adjacent second signal lines in mutually different directions. This leads to an effect that a plurality of magnetic fields with mutually different directions are produced in the region between two adjacent signal lines by two second signal lines through which an electric current flows in mutually different directions.

In addition, according to the first aspect, the second substrate may have both surfaces, one surface of the both surfaces having a circuit arranged on the one surface together with the second signal line. This leads to an effect that a plurality of magnetic fields with mutually different directions are produced by the second signal line wired on the surface of the both surfaces of the second substrate on which the circuit is arranged.

In addition, according to the first aspect, the second substrate may have both surfaces, one surface of the both surfaces having a circuit arranged on the one surface, the other surface having the second signal line wired on the other surface. This leads to an effect that a plurality of magnetic fields with mutually different directions are produced by the second signal line wired on the surface of the both surfaces of the second substrate on which the circuit is not arranged.

In addition, according to the first aspect, the second signal line may be a power line. This leads to an effect that a plurality of magnetic fields with mutually different directions are produced by the power line.

In addition, according to the first aspect, the second substrate may be further provided with dynamic random access memory (DRAM). This leads to an effect that a plurality of magnetic fields with mutually different directions are produced by the second signal line wired on the substrate provided with DRAM.

In addition, according to the first aspect, the first substrate may be further provided with a pixel circuit configured to convert light photoelectrically to generate a pixel signal. This leads to an effect that a plurality of magnetic fields with mutually different directions are produced in the first substrate provided with the pixel circuit.

In addition, according to the first aspect, the semiconductor device may further include a third substrate provided with a signal processing circuit configured to perform predetermined signal processing on the pixel signal. This leads to an effect that the pixel signal is subject to the signal processing.

In addition, according to a second aspect of the present technology, a semiconductor device includes: a first substrate having a plurality of first signal lines wired on the first substrate in a predetermined direction; and a second substrate having a second signal line wired on the second substrate along a path passing through both ends of a predetermined line segment parallel to a direction different from the predetermined direction and through an intermediate point different from any of the both ends of the predetermined line segment. This leads to an effect that a plurality of magnetic fields with mutually different directions are produced in the region between two adjacent signal lines.

### Advantageous Effects of Invention

According to the present technology, it is possible to achieve an advantageous effect capable of reducing electromagnetic noise with ease in a semiconductor device in which a signal lines is wired. Note that effects described herein are not necessarily limitative, and any effect that is desired to be described in the present disclosure may be admitted.

### BRIEF DESCRIPTION OF DRAWINGS

FIG. 1 is a block diagram illustrating an exemplary configuration of an image sensor according to a first embodiment of the present technology.

FIG. 2 is a perspective view illustrating an exemplary configuration of the image sensor according to the first embodiment of the present technology.

FIG. 3 is a cross-sectional view illustrating an exemplary configuration of an image sensor having a front surface arranged to face downward and a back surface on which a power line or the like is wired according to the first embodiment of the present technology.

FIG. 4 is a plan view illustrating an example of magnetic flux distribution in a pixel array according to the first embodiment of the present technology.

FIG. 5 is a diagram illustrating an example of magnetic flux for each pixel of the pixel array according to the first embodiment of the present technology.

FIG. 6 is a plan view illustrating an example of magnetic flux distribution in a pixel array according to a comparative example.

FIG. 7 is a diagram illustrating an example of magnetic flux for each pixel of a pixel array according to a comparative example.

FIG. 8 is a perspective view illustrating an example of an analytic space of an electromagnetic field according to the first embodiment of the present technology.

FIG. 9 is a plan view illustrating an example of a result of simulation according to the first embodiment of the present technology.

FIG. 10 is a plan view illustrating an example of a result of simulation in which the number of terminals is adjusted to be half, according to the first embodiment of the present technology.

FIG. 11 is a plan view illustrating an example of a result of simulation according to a comparative example.

FIG. 12 is a diagram summarizing results of simulation according to the first embodiment of the present technology.

FIG. 13 is a plan view illustrating an example of a memory chip according to a first modification of the first embodiment of the present technology.

FIG. 14 is a plan view illustrating an example of a memory chip according to a second modification of the first embodiment of the present technology.

FIG. 15 is a plan view illustrating an example of a memory chip according to a third modification of the first embodiment of the present technology.

FIG. 16 is a plan view illustrating an example of a memory chip according to a fourth modification of the first embodiment of the present technology.

FIG. 17 is a plan view illustrating an example of a memory chip according to a fifth modification of the first embodiment of the present technology.

FIG. 18 is a plan view illustrating an example of a memory chip according to a sixth modification of the first embodiment of the present technology.

FIG. 19 is a plan view illustrating an example of a memory chip according to a seventh modification of the first embodiment of the present technology.

FIG. 20 is a cross-sectional view illustrating an exemplary configuration of an image sensor having a front surface arranged to face upward and a back surface on which a power line or the like is wired, according to an eighth modification of the first embodiment of the present technology.

FIG. 21 is a cross-sectional view illustrating an exemplary configuration of an image sensor having a front surface, which is arranged to face upward and has a power line or the like wired thereon, according to the eighth modification of the first embodiment of the present technology.

FIG. 22 is a cross-sectional view illustrating an exemplary configuration of an image sensor having a front surface, which is arranged to face downward and has a power line or the like wired thereon, according to the eighth modification of the first embodiment of the present technology.

### MODE(S) FOR CARRYING OUT THE INVENTION

Modes for carrying out the present technology (hereinafter referred to as embodiment) will be described. The description is given in the following order.

1. First embodiment (example in which a power line is wired in an oblique direction)
2. First modification (example in which a part of a power line is wired in an oblique direction)
3. Second modification (example in which a power line is wired along a path bending at three points)
4. Third modification (example in which a power line is wired along a stepped path)
5. Fourth modification (example in which a power line is wired along a plurality of oblique directions)
6. Fifth modification (example in which a part of a power line is wired along a plurality of oblique directions)
7. Sixth modification (example in which a power line is wired in an M-shape)
8. Seventh modification (example in which a power line is wired along a path bending at three points)
9. Eighth modification (example in which a front surface faces upward and a power line is wired in an oblique direction on a back surface)

### 1. First Embodiment

### [Exemplary Configuration of Image Sensor]

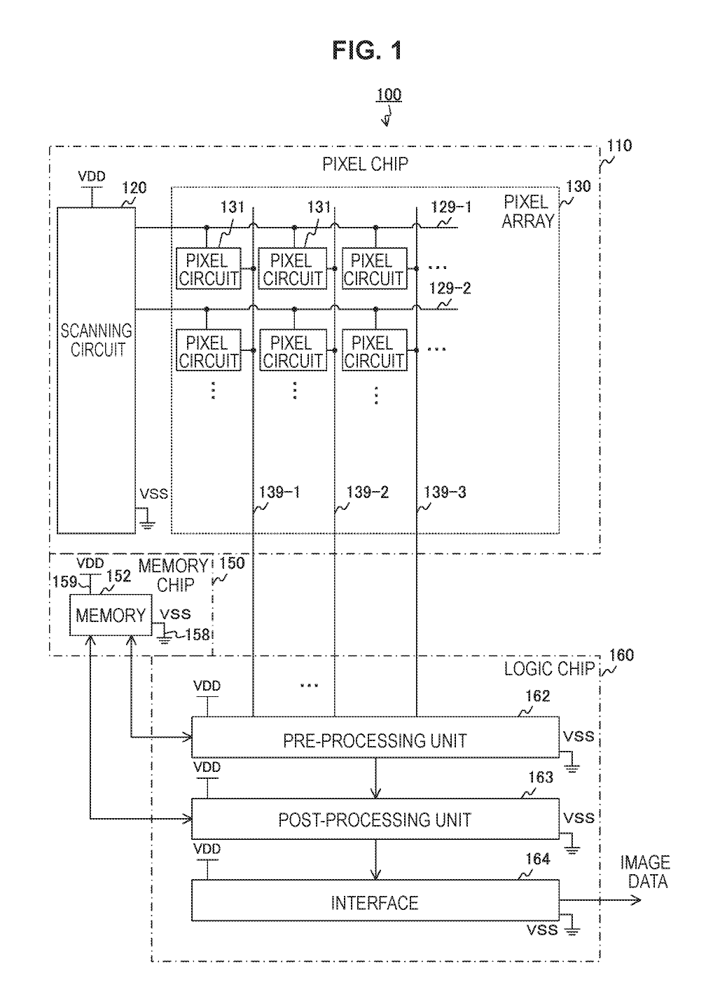

FIG. 1 is a block diagram illustrating an exemplary configuration of an image sensor 100 according to a first embodiment. The image sensor 100 captures image data, and includes three semiconductor chips, that is, a pixel chip 110, a memory chip 150, and a logic chip 160.

The pixel chip 110 is provided with a scanning circuit 120 and a pixel array 130. The pixel array 130 includes a plurality of pixel circuits 131 arrayed in a two-dimensional lattice pattern. A set of pixel circuits 131 arrayed along a predetermined direction is referred to as “row”, and a set of pixel circuits 131 arrayed along a direction perpendicular to the row is referred to as “column”, hereinafter. The number of rows is N (where N is an integer of 2 or more), and the number of columns is M (where M is an integer of 2 or more). Moreover, although both the scanning circuit 120 and the pixel array 130 are arranged in the pixel chip 110, the scanning circuit 120 may be arranged in the memory chip 150, and the pixel array 130 may be arranged in the pixel chip 110. Alternatively, the scanning circuit 120 may be arranged in the logic chip 160.

Further, in the pixel array 130, horizontal signal lines are wired for each row along the row direction, and vertical signal lines are wired for each column along the column direction. The horizontal signal lines corresponding to n rows (where n is an integer of 1 to N) are defined as 129-n, and the vertical signal lines corresponding to m columns (where m is an integer of 1 to M) are defined as 139-m. The pixel circuits 131 having n rows and m columns are connected to the horizontal signal line 129-n and the vertical signal line 139-m.

Moreover, the horizontal signal line 129-n and the vertical signal line 139-m are examples of a first signal line set forth in the claims. In addition, the pixel chip 110 is an example of a first substrate set forth in claims.

The scanning circuit 120 sequentially selects rows, and drives the pixel circuit 131 in the selected row to output a pixel signal. A control signal from the scanning circuit 120 is transmitted to the pixel circuit 131 via the horizontal signal line 129-n.

The pixel circuit 131 photoelectrically converts light to generate a pixel signal under the control of the scanning circuit 120. The pixel circuit 131 supplies the generated pixel signal to a pre-processing unit 162 via the vertical signal line 139-m.

The memory chip 150 includes a memory 152, a ground line 158, and a power line 159. In addition, the logic chip 160 includes the pre-processing unit 162, a post-processing unit 163, and an interface 164. The memory 152 holds pixel data. In one example, the memory 152 can be configured as DRAM. Moreover, the power line 159 is an example of a second signal line set forth in the claims, and the memory chip 150 is an example of a second substrate set forth in the claims.

The pre-processing unit 162 performs predetermined signal processing as pre-processing. In one example, the AD conversion processing for performing AD conversion of a pixel signal from the pixel circuit 131 into pixel data or the correlated double sampling (CDS) processing is executed as the pre-processing. In the CDS processing, the pre-processing unit 162 causes the memory 152 to hold the pixel data immediately after resetting, and acquires a difference between the held pixel data and the pixel data at the time of completion of exposure as pixel data after CDS processing. The pre-processing unit 162 supplies the CDS processed pixel data to the post-processing unit 163. Moreover, the pre-processing unit 162 is an example of a signal processing circuit set forth in the claims, and the logic chip 160 is an example of a third substrate set forth in the claims.

The post-processing unit 163 performs predetermined image processing as post-processing. In one example, demosaicing, white balance processing, color balance processing, or the like is performed as post-processing. The post-processing unit 163 executes post-processing using the memory 152 and generates image data. The post-processing unit 163 then supplies the generated image data to the interface 164.

The interface 164 outputs image data to a circuit outside the image sensor 100.

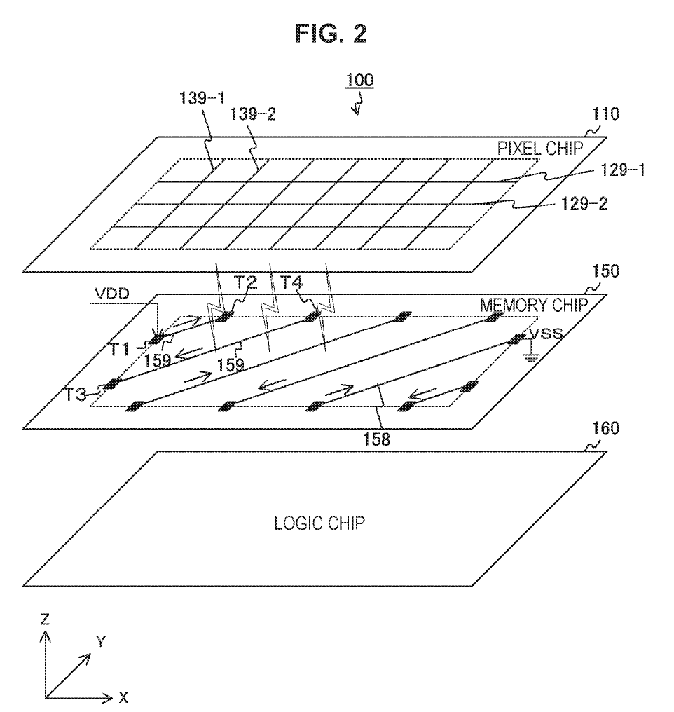

FIG. 2 is a perspective view illustrating an exemplary configuration of the image sensor 100 according to the first embodiment. In the image sensor 100, the memory chip 150 is stacked on top of the logic chip 160, and the pixel chip 110 is stacked on top of the memory chip 150. The direction from the logic chip 160 to the pixel chip 110 is defined as +Z direction or upward direction, and the opposite direction is defined as −Z direction or downward direction, hereinafter. In addition, the row direction is defined as X direction and the column direction is defined as Y direction.

A predetermined number of power lines 159 and ground lines 158 are wired in the memory chip 150, and they are wired along an oblique direction different from any of the X and Y directions. The angle of oblique direction with respect to the X direction may be any angle as long as it corresponds to neither 0 degree nor 90 degrees, but an angle of 45 degrees is the most desirable angle. In addition, electric currents are supplied to the two adjacent signal lines (the power lines 159 or the ground lines 158) in mutually opposite directions. In one example, the power terminals at both ends of one of the two adjacent power lines 159 are defined as T1 and T2, and the power terminals at both ends of the other are defined as T3 and T4. In a case where T3 is adjacent to the power terminal T1 and T2 is adjacent to T4, T1 is a positive terminal, T2 is a negative terminal, T3 is a negative terminal, and T4 is a positive terminal.

The electromagnetic noise may occur in the pixel circuit 131 due to the magnetic field produced from the power line 159. Such a source of noise including the power line 159 is referred to as an aggressor, and a circuit affected by noise, such as the pixel circuit 131, is referred to as a victim.

The power line or the ground line 158 of the logic chip 160 is not necessarily wired along an oblique direction, but in a case where the power line or the ground line 158 of the logic chip 160 can be a source of noise, such power line or the like is also wired along an oblique direction. In addition, the power line or the ground line in each chip is not necessarily the same power wiring connected in the semiconductor chip, and can be connected to each other via wiring on a substrate on which the semiconductor is mounted.

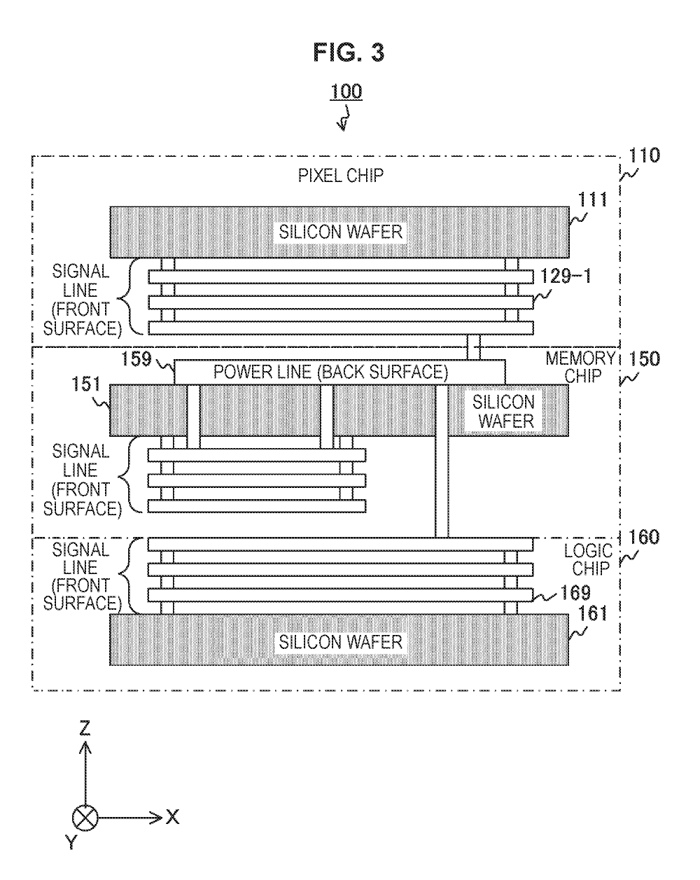

FIG. 3 is a cross-sectional view illustrating an exemplary configuration of the image sensor 100 according to the first embodiment. The pixel chip 110 includes a silicon wafer 111. A circuit such as the pixel circuit 131 and a signal line such as the horizontal signal line 129-1 are arranged on one of both surfaces of the silicon wafer 111. In this manner, a face on which a circuit is arranged in the silicon wafer 111 is typically called a “front surface”.

Further, the memory chip 150 includes a silicon wafer 151. The memory 152 or the signal line is arranged on the front surface of the silicon wafer 151. On the other hand, the power line 159 or the ground line 158 is wired on the back surface, not on the front surface, of both surfaces of the silicon wafer 151. In addition, the back surface of the silicon wafer 151 is arranged at a position facing the front surface of the silicon wafer 111.

The logic chip includes a silicon wafer 161 whose front surface has a circuit such as the pre-processing unit 162 or the signal line 169 arranged thereon.

Moreover, although the image sensor 100 has a three-layer structure in which three substrates are stacked on each other, it is not limited to this structure. In one example, it may have a two-layer structure. In this case, in one example, the scanning circuit 120 and the pixel array 130 are provided on one of the two semiconductor chips, and the memory 152 and the pre-processing unit 162 are provided on the other. In addition, although the pixel chip 110, the memory chip 150, and the logic chip 160 are stacked in this order from above, the stacking order between them is not limited to this order. In one example, the pixel chip 110, the logic chip 160, and the memory chip 150 can be stacked in this order from above.

Further, although the victim (the horizontal signal line or vertical signal line, etc.) is wired in the row direction or the column direction, the victim can be wired in an oblique direction. In this case, the aggressor (the power line 159, etc.) may be wired in a direction different from the oblique direction.

Further, the power line or the ground line is wired in an oblique direction in the image sensor 100. However, the signal line such as the power line 159 may be wired in a semiconductor device other than the image sensor 100 in an oblique direction as long as the semiconductor device can convert a signal input from the outside into an electric signal. In particular, the semiconductor device capable of processing an analog signal is considered to be highly useful. Examples of the semiconductor device to be applied include various sensors, communication devices, various antennas, display devices, and the like. In addition, the substrate to be wired in an oblique direction is not limited to a semiconductor substrate (semiconductor chip), and may be a substrate other than a semiconductor substrate, such as a printed board. Moreover, the image sensor 100 is an example of a semiconductor device set forth in the claims.

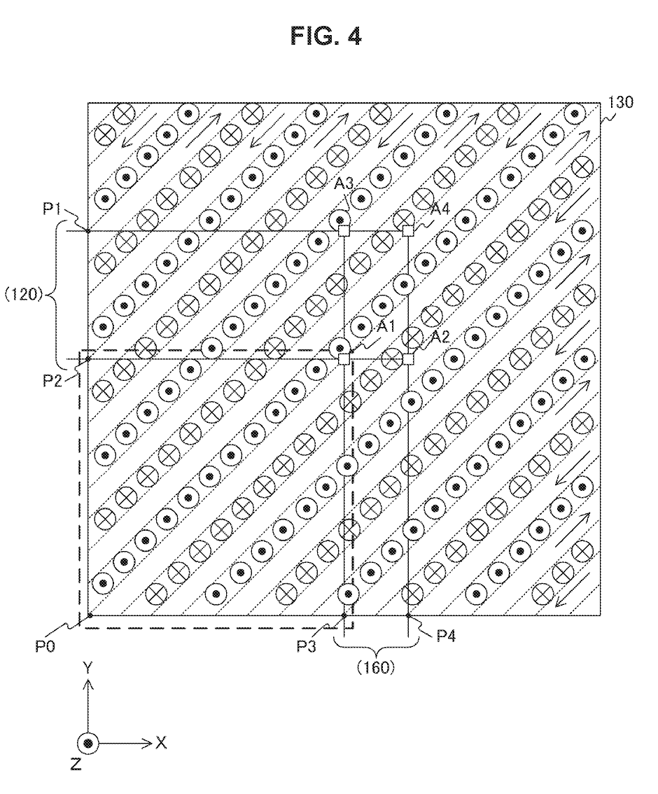

FIG. 4 is a plan view illustrating an example of the magnetic flux distribution in the pixel array 130 according to the first embodiment. In this figure, the arrow indicates the direction of an electric current flowing through the power line 159 or the ground line 158 arranged below the pixel array 130. In accordance with the right hand screw rule, a magnetic field in the +Z direction is produced in one side of both ends of the power line 159 or the like, and a magnetic field in the −Z direction is produced in the other. The intensity of electromagnetic noise of the pixel circuit 131 due to this magnetic field can be estimated by assuming a conductor loop passing through the pixel circuit 131. Here, the conductor loop means a signal line wired along the path as follows.

Power supply circuit→Scanning circuit 120→Pixel circuit 131→Logic chip 160→Power supply circuit

The region surrounded by this conductor loop is represented by a rectangular region having the horizontal signal line 129-n from the scanning circuit 120 to the pixel circuit 131 and the vertical signal line 139-1 from the pixel circuit 131 to the logic chip 160 as two sides. The fluctuation in the magnetic flux passing through the rectangular region in the conductor loop causes the induced electromotive force in a signal (e.g., a pixel signal) flowing through the conductor loop in accordance with the laws of electromagnetic induction. This induced electromotive force is treated as an offset different from the signal corresponding to the exposure amount in the pixel signal. In addition, the dimensions of the conductor loop (rectangular region) differ depending on the position of the pixel. Thus, the offset component due to the induced electromotive force is not necessarily the same for each pixel. If the difference for each pixel of the offset component is large, the difference appears as electromagnetic noise in the image data. Thus, the intensity of electromagnetic noise can be estimated from the amount of magnetic flux in this rectangular region.

In the rectangular region, the opposite angle of a pixel A1 is defined as a point P0, hereinafter. In addition, an intersection point between the horizontal signal line 129-n passing through the pixel A1 and the boundary of the pixel array 130 is defined as P2, and an intersection point between the vertical signal line 139-m passing through the pixel A1 and the boundary of the pixel array 130 is defined as P2. An intersection point between the vertical signal line 139-(m+1) passing through a pixel A2 adjacent to the pixel A1 in the row direction and the boundary of the pixel array 130 is defined as P4. An intersection point between the horizontal signal line 129-(n−1) passing through a pixel A3 adjacent to the pixel circuit A1 in the column direction and the boundary of the pixel array 130 is defined as P1.

In one example, the intensity of electromagnetic noise of the pixel A1 is a value corresponding to the amount of magnetic flux in the rectangular region whose vertexes are P0, P2, A1, and P3. In addition, the intensity of electromagnetic noise of the pixel A2 is a value corresponding to the amount of magnetic flux in the rectangular region whose vertexes are P0, P2, A2, and P4. In one example, the amount of magnetic flux is counted by setting the magnetic flux per mark indicating the +Z direction as “+1” and the magnetic flux per mark indicating the −Z direction as “−1”.

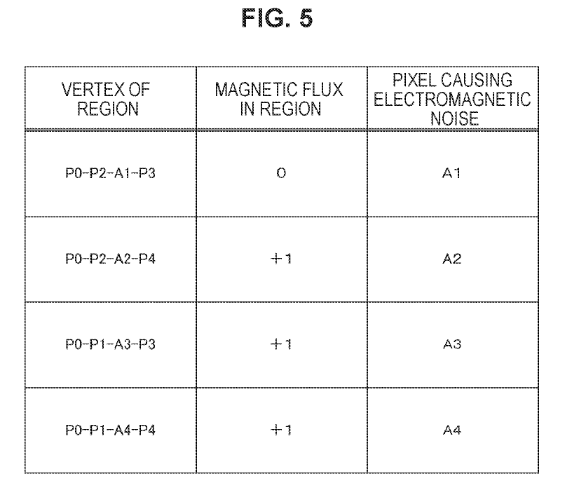

FIG. 5 is a diagram illustrating an example of the magnetic flux for each pixel in the pixel array according to the first embodiment. The sum of magnetic flux in the region with vertexes P0, P2, A1, and P3 corresponding to the pixel A1 is “0”. In addition, the sum of magnetic flux in the region with vertexes P0, P2, A2, and P4 corresponding to the pixel A2 is “+1”. In this way, there is little difference between the amounts of magnetic flux corresponding to the pixels A1 and A2 adjacent to each other. This is because, as illustrated in FIG. 4, the wiring including the power line 159 or the like in an oblique direction causes magnetic fields to be produced in +Z and −Z directions in the region between the vertical signal line passing through the pixel A1 and the vertical signal line passing through the pixel A2, then these magnetic fields are cancelled out. This allows the difference between induced electromotive forces caused by the magnetic fields to be reduced in each of the adjacent pixels. Thus, it is possible to reduce electromagnetic noise.

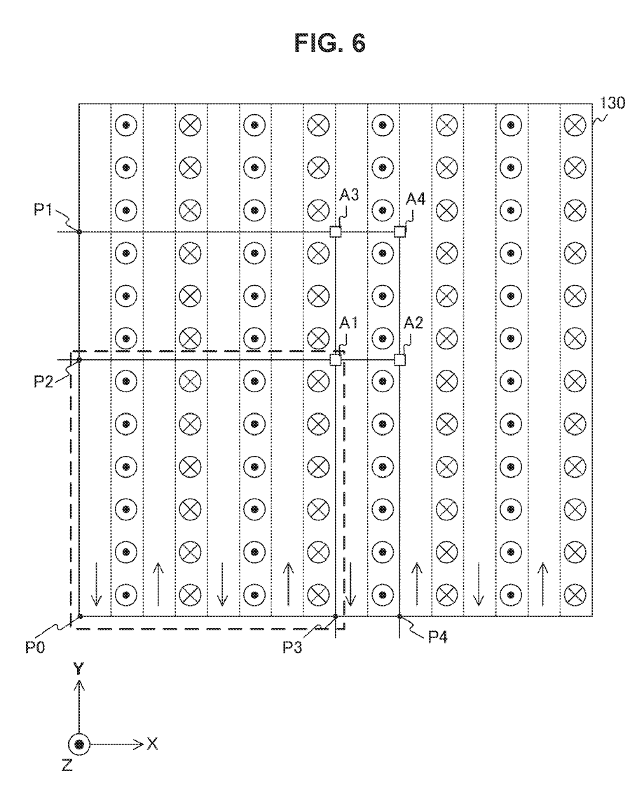

FIG. 6 is a plan view illustrating an example of the magnetic flux distribution in the pixel array 130 according to a comparative example. In this comparative example, it is assumed that the power line 159 or the ground line 158 is wired along the Y (column) direction in the lower memory chip. In this figure, the arrow indicates the direction of electric current flowing through the power line 159 or the like below the pixel array.

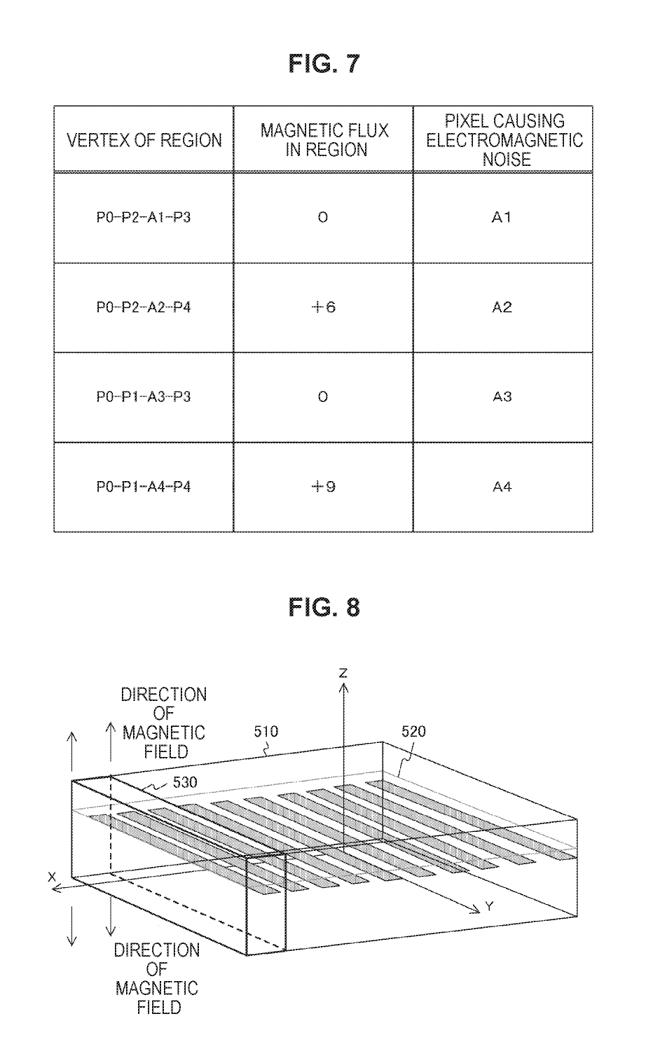

FIG. 7 is a diagram illustrating an example of the magnetic flux for each pixel in the pixel array in the comparative example. The sum of magnetic flux in the region with vertexes P0, P2, A1, and P3 corresponding to the pixel A1 is “0”. In addition, the sum of magnetic flux in the region with vertexes P0, P2, A2, and P4 corresponding to the pixel A2 is “+6”. In this manner, a large difference occurs in the amounts of magnetic flux in the regions corresponding to the pixels A1 and A2 adjacent to each other. This is because, as illustrated in FIG. 6, the wiring such as the power line 159 in the Y direction causes the magnetic field in the +Z direction to be concentrated in the region between the vertical signal line passing through A1 and the vertical signal line passing through A2. This makes the difference in the induced electromotive force caused by the magnetic field relatively large in each of the pixels adjacent to each other. Accordingly, streak-shaped electromagnetic noise will occur along the Y direction in the image data.

On the other hand, the wiring of the power line 159 or the ground line 158 in an oblique direction makes it possible to reduce the difference in the induced electromotive forces produced in each of the pixels adjacent to each other, thereby reducing the electromagnetic noise occurring in the image data as illustrated in FIGS. 5 and 6.

FIG. 8 is a perspective view illustrating an example of an analytic space 510 of magnetic field, according to the first embodiment. The length of the analytic space 510 in the Z direction is 4 millimeters (mm), and the length in the Y direction is 4 millimeters (mm). The length in the X direction is determined by a boundary condition of 20 micrometers (μm). If the analytic space 510 is small, accurate analysis fails to be performed. Thus, the analytic space 510 is large to some extent.

Further, a plane 520 of the victim (e.g., the pixel array 130) is set to be located 5 micrometers (μm) above the aggressor (e.g., the power line 159). The width of the power line 159 or the ground line 158 is set to 10 micrometers (μm) and the spacing is set to 10 micrometers (μm). The electric current flowing through the power line 159 or the ground line 158 is set to 10 milliampere (mA) per line, and the frequency of the pixel signal is set to 5 megahertz (MHz). In addition, the number of pixels is set to 100 rows×100 columns. In the analytic space 510, in one example, analysis is performed for each space unit 530 corresponding to the wiring width.

In the above-described analytic space 510, the distribution of electromagnetic fields can be obtained by simulation using high frequency structural simulator (HFSS, registered trademark) at ANSYS Inc.

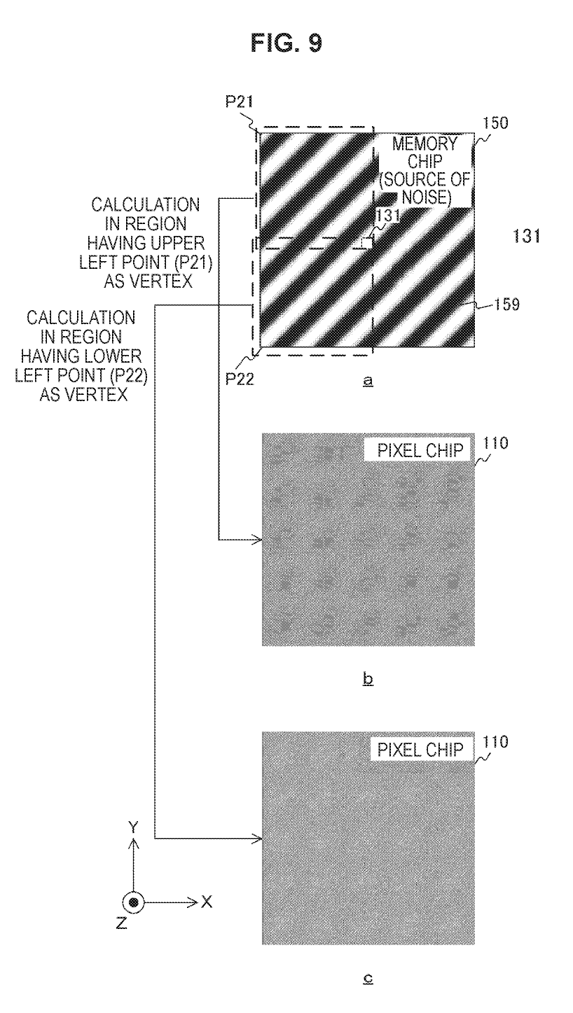

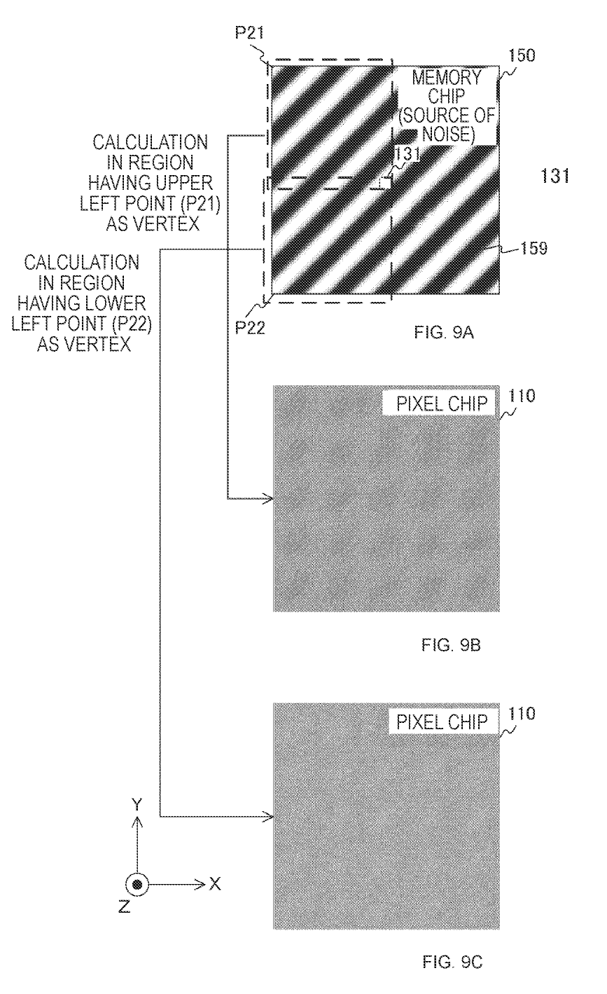

FIG. 9 is a plan view illustrating an example of a result of simulation, according to the first embodiment. This result of simulation is a result obtained by performing noise simulation by further discretizing the distribution data obtained using HFSS (registered trademark). In this figure, the portion a is a plan view illustrating an example of the wiring of the power line 159 or the like on the memory chip 150. The power line 159 or the like is wired in an oblique direction. In this figure, the portion b is a plan view illustrating the electromotive force distribution in the pixel chip 110 that is calculated from the magnetic flux distribution in the rectangular region having the pixel circuit 131 and an upper left point P21 of the memory chip 150 as vertexes. In this figure, the portion c is a plan view illustrating the electromotive force distribution in the pixel chip 110 that is calculated from the magnetic flux distribution in the rectangular region having the pixel circuit 131 and a lower left point P22 of the memory chip 150 as vertexes. In this figure, the portions b and c are represented by the magnitude of the induced electromotive force using brightness. In addition, in this figure, the portions b and c assume that the positions of the terminals connected to the logic chip 160 are different.

In the case where the power line 159 or the ground line 158 is wired along an oblique direction as illustrated in the portions b and c of FIG. 9, the distribution of electromotive forces becomes nearly uniform. This makes it possible to reduce electromagnetic noise occurring in the image data.

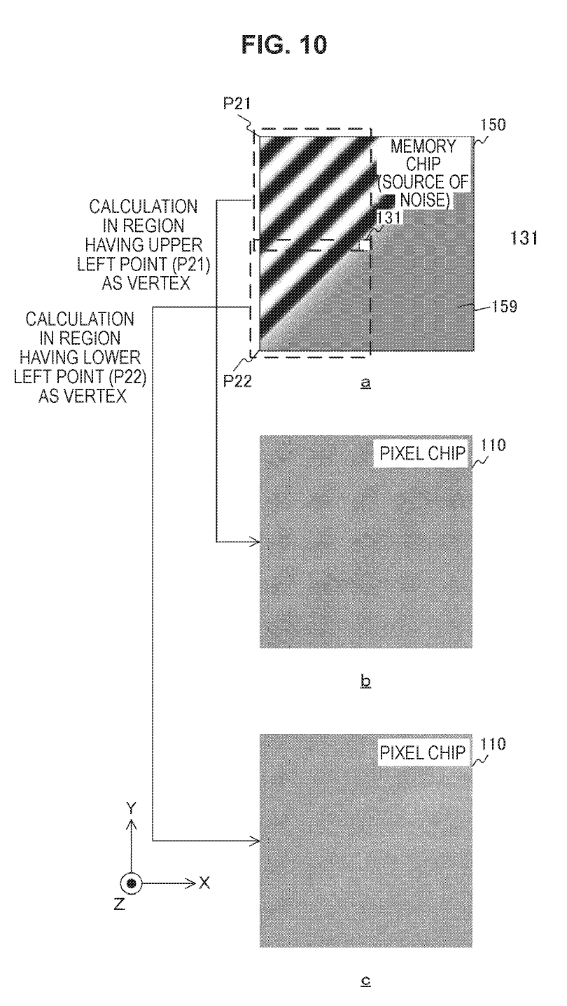

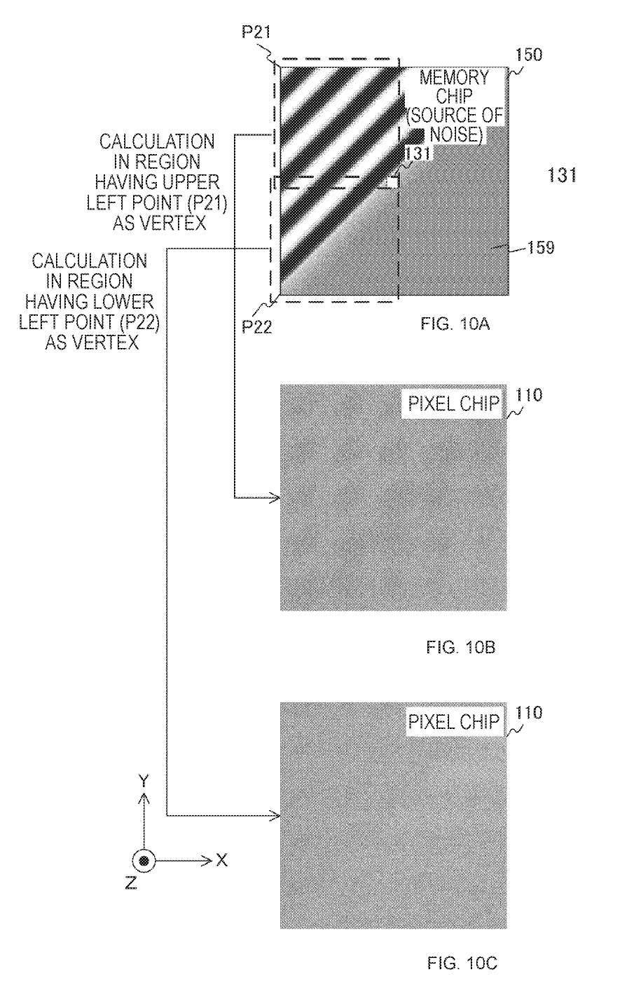

FIG. 10 is a plan view illustrating an example of a result of simulation in which the number of terminals is adjusted to be half, according to the first embodiment. In this figure, the portion a is a plan view illustrating an example of the wiring of the power line 159 or ground line 158 on the memory chip 150. The power line 159 or the like is wired in an oblique direction. In this figure, the portion b is a plan view illustrating the electromotive force distribution in the pixel chip 110 that is calculated from the magnetic flux distribution in the rectangular region having the pixel circuit 131 and the upper left point P21 of the memory chip 150 as vertexes. In this figure, the portion c is a plan view illustrating the electromotive force distribution in the pixel chip 110 that is calculated from the magnetic flux distribution in the rectangular region having the pixel circuit 131 and the lower left point P22 of the memory chip 150 as vertexes.

In FIG. 10, the number of terminals is adjusted to be half as compared with that of FIG. 9 in such a way that the number of terminals is the same as that of a comparative example to be described later. In addition, in this case, the electromotive force distribution also becomes nearly uniform as illustrated in the portions b and c of FIG. 10, thereby reducing electromagnetic noise.

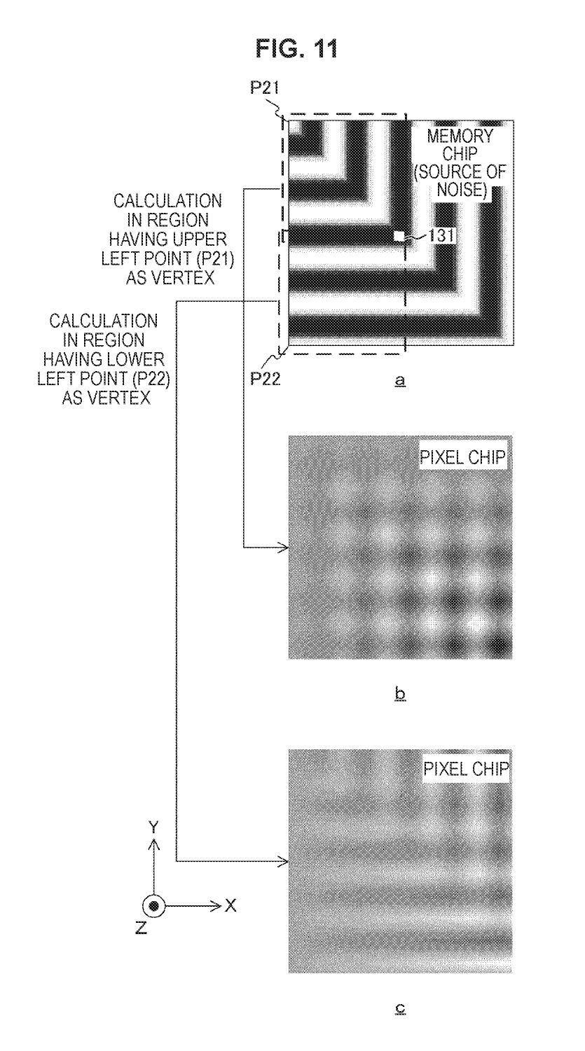

FIG. 11 is a plan view illustrating an example of a result of simulation in a comparative example. This comparative example assumes that the power lines 159 or the ground lines 158 are wired along the X (row) direction and the Y (column) direction in the memory chip 150. In this figure, the portion a is a plan view illustrating an example of the wiring of the power line 159 or the like on the memory chip 150. In this figure, the portion b is a plan view illustrating the electromotive force distribution in the pixel chip 110 that is calculated from the magnetic flux distribution in the rectangular region having the pixel circuit 131 and the upper left point P21 of the memory chip 150 as vertexes. In this figure, the portion c is a plan view illustrating the electromotive force distribution in the pixel chip 110 that is calculated from the magnetic flux distribution in the rectangular region having the pixel circuit 131 and the lower left point P22 of the memory chip 150 as vertexes.

In a case where the power lines 159 or the ground line 158 are wired along the X direction and the Y direction as illustrated in the portions b and c of FIG. 11, the electromotive force distribution becomes non-uniform. This will cause streak-shaped noise in the X direction and the Y direction.

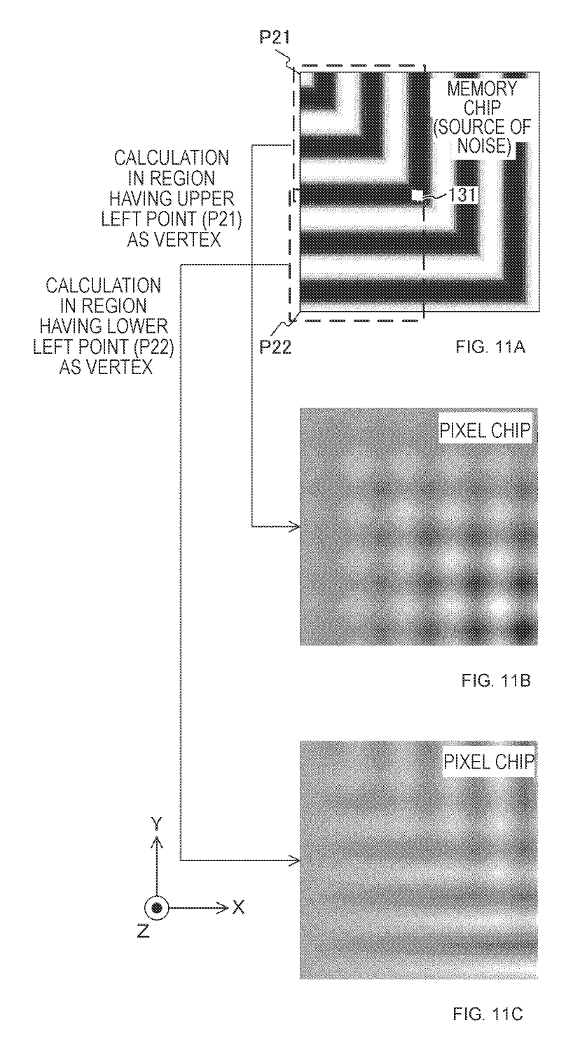

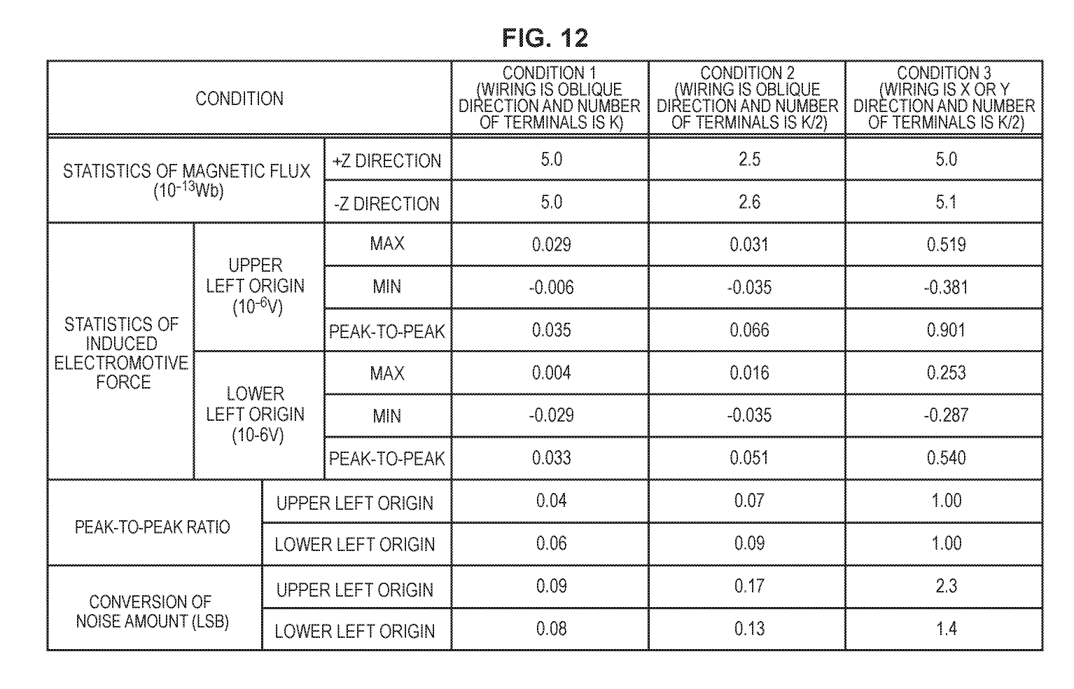

FIG. 12 is a diagram summarizing results of simulation according to the first embodiment. A simulation condition where the power line 159 or the ground line 158 is wired in an oblique direction and the number of terminals is set to K (where K is an integer) is defined as Condition 1. A simulation condition where the wiring is in an oblique direction and the number of terminals is set to K/2 is defined as Condition 2. In addition, a simulation condition where the power source lines 159 or the ground lines 158 are wired in the X direction and the Y direction and the number of terminals is set to K/2 is defined as Condition 3.

The sum of magnetic flux is almost the same between Condition 1 and Condition 3, and the sum of magnetic flux in Condition 2 is smaller than that in Condition 3. In addition, the difference between the maximum value and the minimum value of the induced electromotive forces in the pixel chip 110 is relatively small in Conditions 1 and 2. In addition, the peak-to-peak value between the induced electromotive forces is relatively small in Conditions 1 and 2. Here, as the difference between the maximum value and the minimum value of the induced electromotive forces or the peak-to-peak value is larger, the difference between the brightness and the darkness among pixels stands out, which causes it to make more noticeable noise in visual observation. Thus, noise is relatively small in Conditions 1 and 2. In one example, in Conditions 1 and 2, a value for converting the noise amount of least significant bit (LSB) is smaller than that in Condition 3.

In this manner, oblique wiring of the power line 159 or the ground line 158 makes it possible to reduce electromagnetic noise due to the magnetic field from the power line 159 or the like. In this configuration, there is no need to provide an extra resource such as an electromagnetic shield and the number of necessary wiring patterns is only one layer, so the applicable range is very wide.

Moreover, in the image sensor 100, the power line 159 or the ground line 158 is used as a source of noise and the wiring direction thereof is made oblique. However, in a case where a signal line other than the power line 159 or the ground line 158 is assumed as a source of noise, the wiring direction may be made oblique. In one example, the signal line connected to memory cells inside the memory 152 may be wired in an oblique direction.

In this manner, according to the first embodiment of the present technology, the power line 159 or the ground line 158 is wired in an oblique direction so that magnetic fields in the +Z and −Z directions are produced in the region between the vertical signal lines adjacent to each other. Thus, it is possible to reduce electromagnetic noise produced in the pixel signal due to the magnetic field.

### First Modification

In the first embodiment described above, the power line 159 or the like is wired in an oblique direction wholly from one of both ends of the power line 159 or the ground line 158 to the other. However, it is not limited to this configuration as long as magnetic fields in the +Z and −Z directions are produced in the region between the vertical signal lines adjacent to each other. In one example, a part of the power line 159 or the like may be wired along the X direction or the Y direction, and the remaining part may be wired in an oblique direction. The image sensor 100 according to the first embodiment is different from that of the first embodiment in that a part of the power line 159 or the like is wired in an oblique direction.

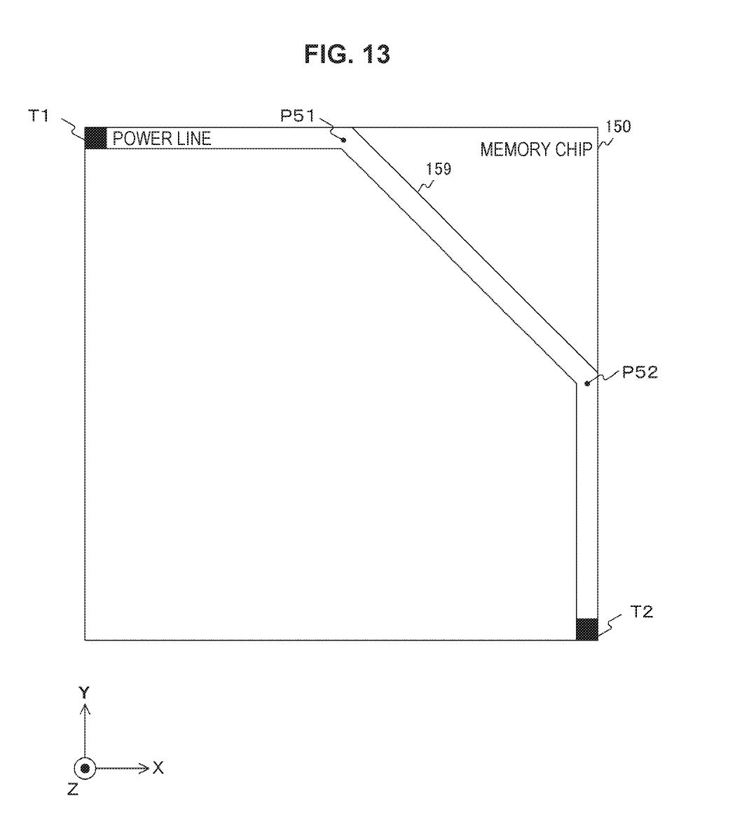

FIG. 13 is a plan view illustrating an example of the memory chip 150 according to a first modification of the first embodiment. In this figure, only one power line 159 is shown, and the remaining power lines 159 and ground line 158 are omitted. In the first modification of the first embodiment, the power line 159 is wired in the X direction from the power terminal T1 to a bending point P51 and it is wired in an oblique direction from the bending point P51 to a bending point P52. Then, the wiring is made from the bending point P52 to the power terminal T2 in the Y direction. In this manner, a part of the power line 159 from the bending point P51 to the bending point P52 is wired in an oblique direction, and the remaining part is wired in the X direction or the Y direction.

In this manner, according to the first modification of the first embodiment of the present technology, a part of the power line 159 or the ground line 158 is wired along the X direction or the Y direction, and the remaining part is wired in an oblique direction, thereby reducing the electromagnetic noise.

### Second Modification

In the first embodiment described above, the power line 159 or the ground line 158 is wired in an oblique direction. However, if magnetic fields in the +Z and −Z directions are produced in the region between the vertical signal lines adjacent to each other, it is not limited to this configuration. Such a magnetic field can be produced by allowing the power line 159 or the like to be wired along a path passing through both ends of a line segment parallel to an oblique direction and through an intermediate point between both ends thereof. As such a wiring method, a method of wiring the power line 159 or the like along a path bending at three points is conceivable, in addition to a method of wiring the power line 159 or the like along an oblique direction as described in the first embodiment. Among them, the wiring in the oblique direction is prohibited in the design rule of the semiconductor process in some cases. In this case, the wiring along a path bending at three points can be used. The image sensor 100 according to a second modification of the first embodiment is different from that of the first embodiment in that the power line 159 or the like is wired along a path bending at three points.

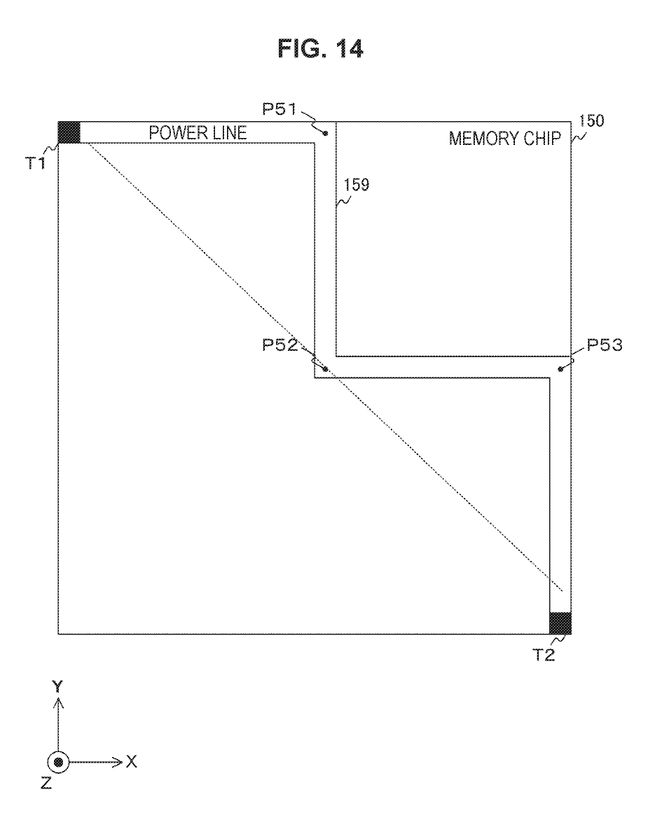

FIG. 14 is a plan view illustrating an example of the memory chip 150 according to the second modification of the first embodiment. In this figure, only one power line 159 is shown, and the remaining power lines 159 and ground lines 158 are omitted. In the second modification of the first embodiment, the power line 159 is wired in the X direction from the power terminal T1 to the bending point P51 and is wired in the Y direction from the bending point P51 to the bending point P52. Then, the power line 159 is wired in the X direction from the bending point P52 to the bending point P53 and is wired in the Y direction from the bending point P53 to the power terminal T2. Such wiring allows the power line 159 to pass through both ends of a line segment in an oblique direction indicated by a dotted line and through an intermediate point between both ends thereof.

In this manner, according to the second modification of the first embodiment of the present technology, the power line 159 or the ground line 158 is wired along the path bending at three points, so it is possible to reduce electromagnetic noise even in a case where the wiring in an oblique direction is prohibited.

### Third Modification

In the first embodiment described above, the power line 159 or the ground line 158 is wired in an oblique direction. However, if magnetic fields in the +Z and −Z directions are produced in the region between the vertical signal lines adjacent to each other, it is not limited to this configuration. In one example, it is conceivable that the wiring is performed along a stepped path bending at four or more bending points. The image sensor 100 according to a third modification of the first embodiment is different from that of the first embodiment in that the power line 159 or the like is wired along a stepped path.

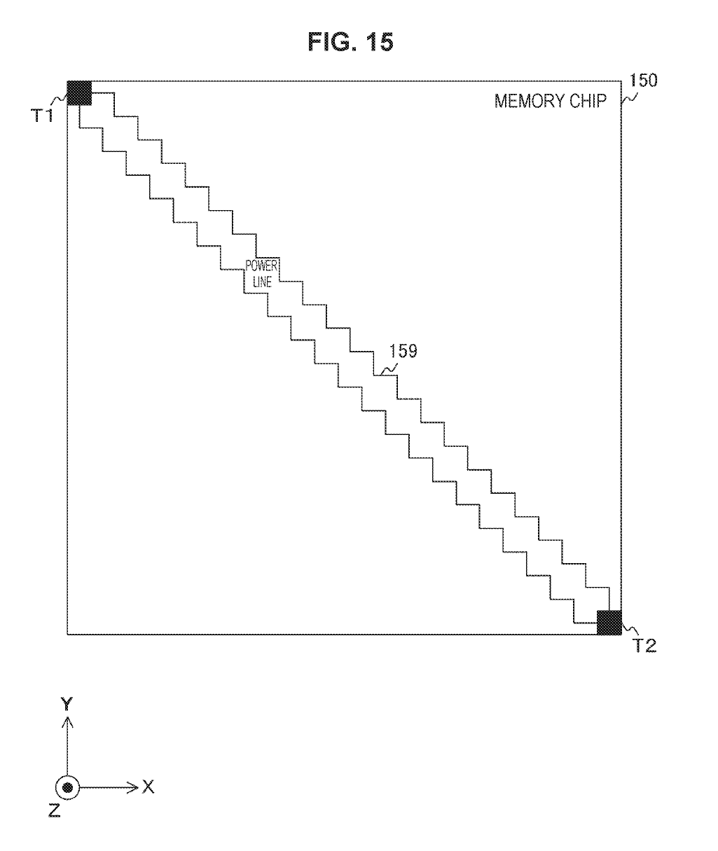

FIG. 15 is a plan view illustrating an example of the memory chip 150 according to the third modification of the first embodiment. In this figure, only one power line 159 is shown, and the remaining power lines 159 and ground lines 158 are omitted. In the third modification of the first embodiment, the power line 159 is wired along a stepped path that connects two power terminals T1 to T2 having different X coordinate and Y coordinate. It can be seen that the path of the power line 159 is wired macroscopically in an oblique direction.

In this manner, according to the third modification of the first embodiment of the present technology, the power line 159 or the ground line 158 is wired along the stepped path bending at four or more points, so the wiring in an oblique direction is achieved as viewed macroscopically.

### Fourth Modification

In the first embodiment described above, the power line 159 or the like is wired in an oblique direction wholly at the same angle from one of both ends of the power line 159 or the ground line 158 to the other. However, it is not limited to this configuration as long as magnetic fields in the +Z and −Z directions are produced in the region between the vertical signal lines adjacent to each other. In one example, a part of the power line 159 or the like may be wired in an oblique direction at an angle R1 (where R1 is a real number), and the remaining part may be wired in an oblique direction at an angle R2 (where R2 is a real number) different from the angle R1. The image sensor 100 according to a fourth modification of the first embodiment is different from that of the first embodiment in that a part of the power line 159 or the like and the remaining part are wired along a plurality of oblique directions having different angles from each other.

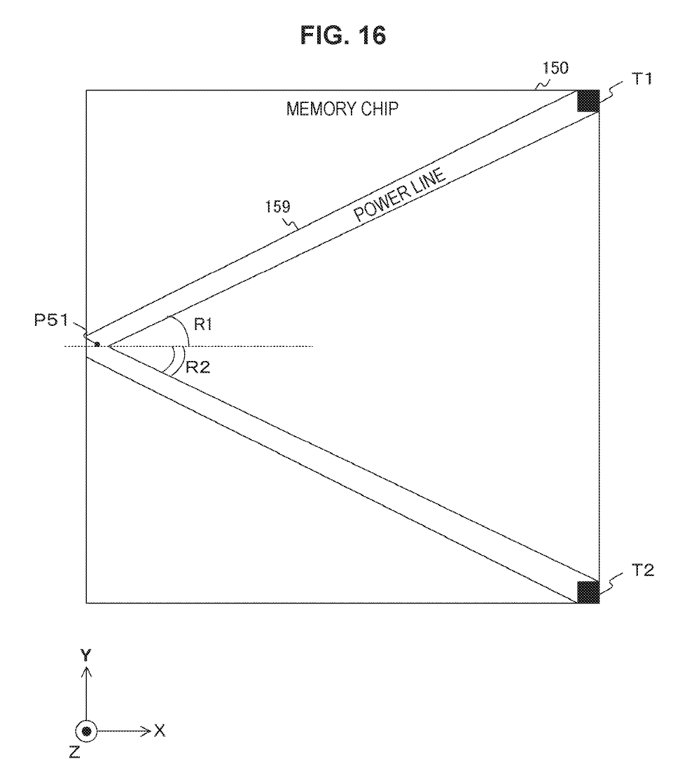

FIG. 16 is a plan view illustrating an example of the memory chip 150 according to the fourth modification of the first embodiment. In this figure, only one power line 159 is shown, and the remaining power lines 159 and ground lines 158 are omitted. In the fourth modification of the first embodiment, the part from the power terminal T1 to the bending point P51 of the power line 159 is wired along an oblique direction at R1 with respect to the X direction. The value of R1 is an angle that corresponds to neither 0 nor 90 degrees. In addition, the part from the bending point P51 to the power terminal T2 of the power line 159 is wired in an oblique direction of R2 with respect to the X direction. The value of R2 is an angle that corresponds to neither 0 nor 90 degrees. Such wiring allows the wiring shape of the power line 159 to be V-shaped when viewed in transverse.

In this manner, according to the fourth modification of the first embodiment of the present technology, the power line 159 or the ground line 158 is wired along a plurality of oblique directions having different angles from each other, thereby reducing electromagnetic noise.

### Fifth Modification

In the first embodiment described above, the power line 159 or the like is wired in an oblique direction wholly from one of both ends of the power line 159 or the ground line 158 to the other. However, it is not limited to this configuration as long as magnetic fields in the +Z and −Z directions are produced in the region between the vertical signal lines adjacent to each other. In one example, a part of the power line 159 or the like may be wired along the Y direction, another part may be wired in an oblique direction at the angle R, and the other parts may be wired along an oblique direction at the angle R2. The image sensor 100 according to a fifth modification of the first embodiment is different from that of the first embodiment in that a part of the power line 159 or the like is wired along the Y direction and the remaining part is wired along a plurality of oblique directions having different angles from each other.

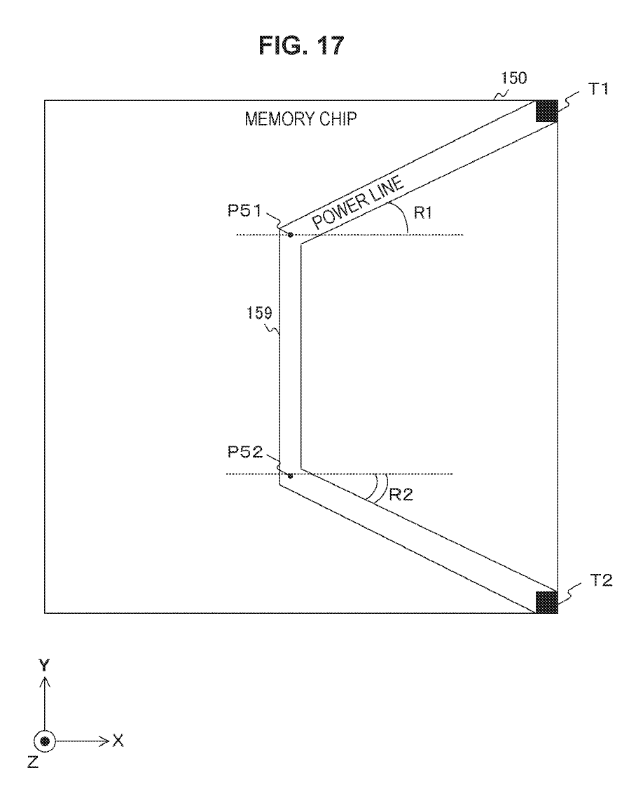

FIG. 17 is a plan view illustrating an example of the memory chip 150 according to the fifth modification of the first embodiment. In this figure, only one power line 159 is shown, and the remaining power lines 159 and ground lines 158 are omitted. In the fifth modification of the first embodiment, the power line 159 is wired in an oblique direction at the angle R1 from the power terminal T1 to the bending point P51, and is wired from the bending point P51 to the bending point P52 in the Y direction, then is wired in an oblique direction at the angle R2 from the bending point P52 to the power terminal T2.

In this manner, according to the fifth modification of the first embodiment of the present technology, a part of the power line 159 or the ground line 158 is wired along the Y direction and the remaining part is wired along a plurality of oblique directions having different angles from each other, thereby reducing electromagnetic noise.

### Sixth Modification

In the first embodiment described above, the power line 159 or the like is wired in an oblique direction wholly from one of both ends of the power line 159 or the ground line 158 to the other. However, it is not limited to this configuration as long as magnetic fields in the +Z and −Z directions are produced in the region between the vertical signal lines adjacent to each other. In one example, the power line 159 or the like can be wired to be M-shaped. The image sensor 100 according to a sixth modification of the first embodiment is different from that of the first embodiment in that the power line 159 or the like is wired to be M-shaped.

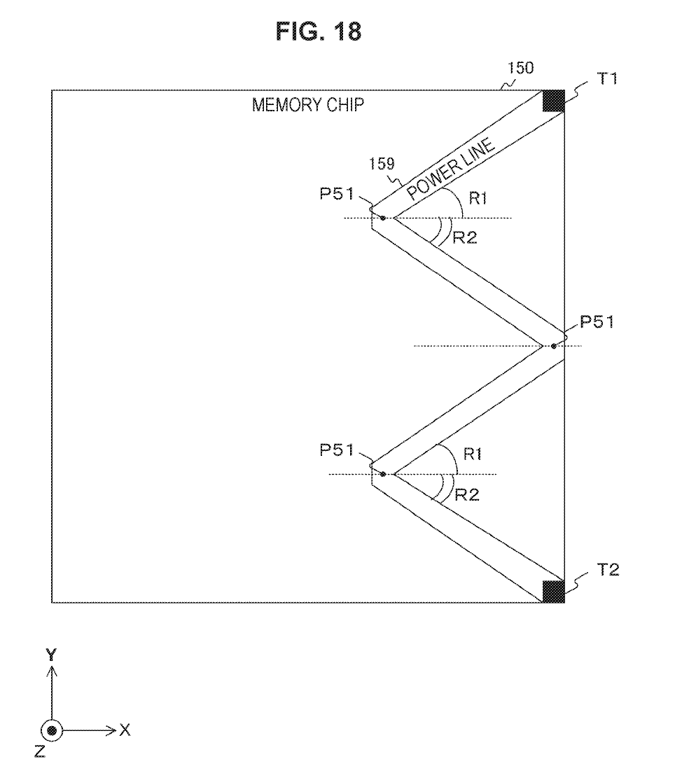

FIG. 18 is a plan view illustrating an example of the memory chip 150 according to the sixth modification of the first embodiment. In this figure, only one power line 159 is shown, and the remaining power lines 159 and ground lines 158 are omitted. In the sixth modification of the first embodiment, the power line 159 is wired in an oblique direction at the angle R1 from the power terminal T1 to the bending point P51, and is wired in an oblique direction at the angle R2 from the bending point P51 to the bending point P52. Then, the power line 159 is wired in an oblique direction at the angle R1 from the bending point P52 to the bending point P53, and is wired along an oblique direction at the angle R2 from the bending point P53 to the power terminal T2. Such wiring allows the wiring shape of the power line 159 to be M-shaped when viewed in transverse.

In this manner, according to the sixth modification of the first embodiment of the present technology, the power line 159 or the ground line 158 is wired to be M-shaped, thereby reducing electromagnetic noise.

### Seventh Modification

In the first embodiment described above, the power line 159 or the ground line 158 is wired in an oblique direction. However, it is not limited to this configuration as long as magnetic fields in the +Z and −Z directions are produced in the region between the vertical signal lines adjacent to each other. Such a magnetic field can be produced by allowing the power line 159 or the like to be wired along a path passing through both ends of a line segment parallel to the oblique direction and through an intermediate point between both ends thereof. As such a wiring method, a method of wiring the power line 159 or the like along a path bending at three points is conceivable, in addition to a method of wiring the power line 159 or the like along an oblique direction as described in the first embodiment. The image sensor 100 according to a seventh modification of the first embodiment is different from that of the first embodiment in that the power line 159 or the like is wired along a path bending at three points.

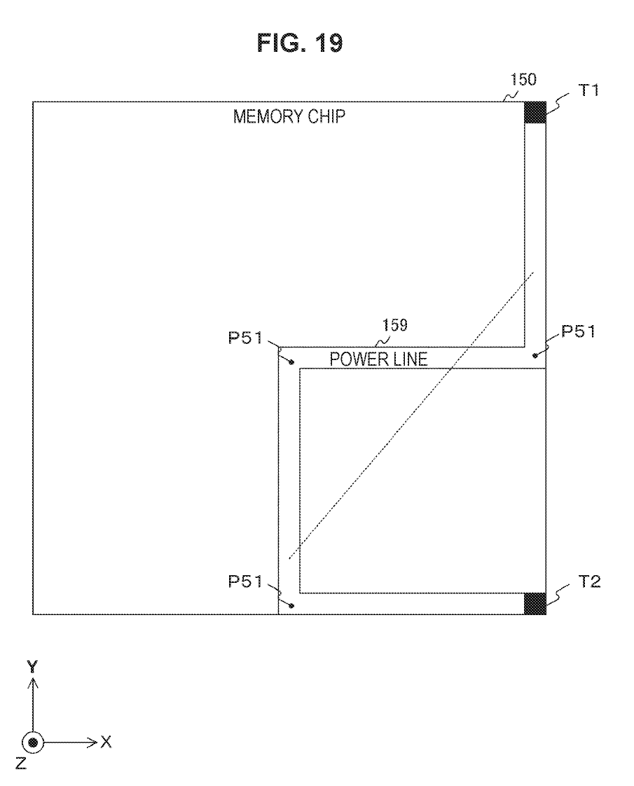

FIG. 19 is a plan view illustrating an example of the memory chip 150 according to the seventh modification of the first embodiment. In this figure, only one power line 159 is shown, and the remaining power lines 159 and ground lines 158 are omitted. In the seventh modification of the first embodiment, the power line 159 is wired in the Y direction from the power terminal T1 to the bending point P51, and is wired in the X direction from the bending point P51 to the bending point P52. Then, the power line 159 is wired in the Y direction from the bending point P52 to the bending point P53, and is wired in the X direction from the bending point P53 to the power terminal T2. Such wiring allows the power line 159 to pass through both ends of a line segment in an oblique direction indicated by a dotted line and through an intermediate point between both ends thereof.

In this manner, according to the seventh modification of the first embodiment of the present technology, the power line 159 or the ground line 158 is wired along the path bending at three points, so it is possible to reduce electromagnetic noise even in a case where the wiring in an oblique direction is prohibited.

### Eighth Modification

In the first embodiment described above, the silicon wafer 151 is arranged so that its front surface faces downward, but the silicon wafer 151 may be arranged so that its front surface faces upward. The image sensor 100 according to an eighth modification of the first embodiment is different from that of the first embodiment in that the silicon wafer 151 is arranged so that its front surface faces upward.

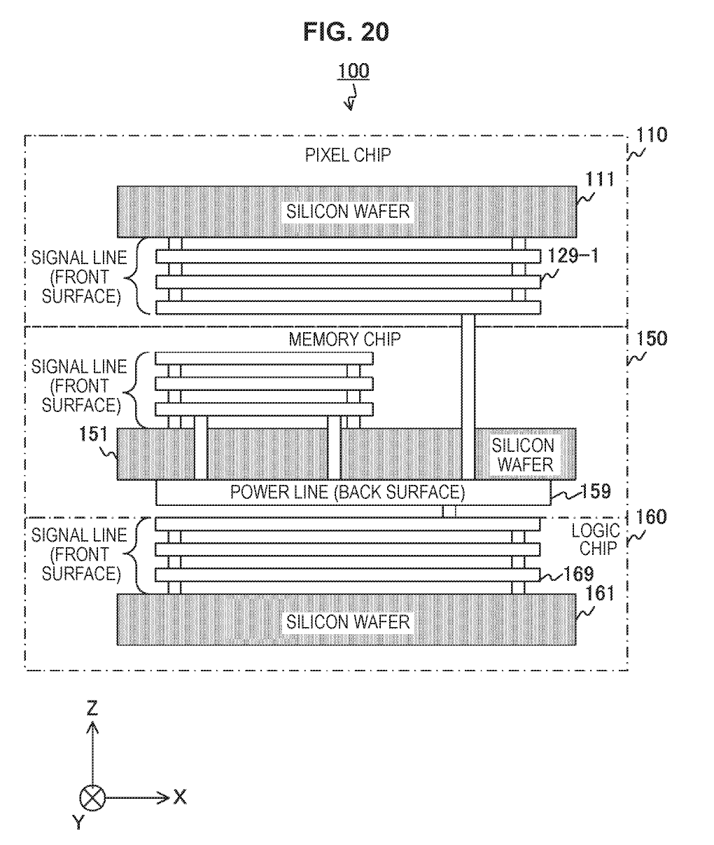

FIG. 20 is a cross-sectional view illustrating an exemplary configuration of the image sensor 100 according to the eighth modification of the first embodiment. The image sensor 100 according to the eighth modification of the first embodiment is different from that of the first embodiment in that the silicon wafer 151 is arranged so that its front surface faces upward. In this case, from the viewpoint of reduction of electromagnetic noise by setting the distance to the victim (the pixel array 130) to be remote, the power line 159 or the ground line 158 is wired on the back surface of the silicon wafer 151.

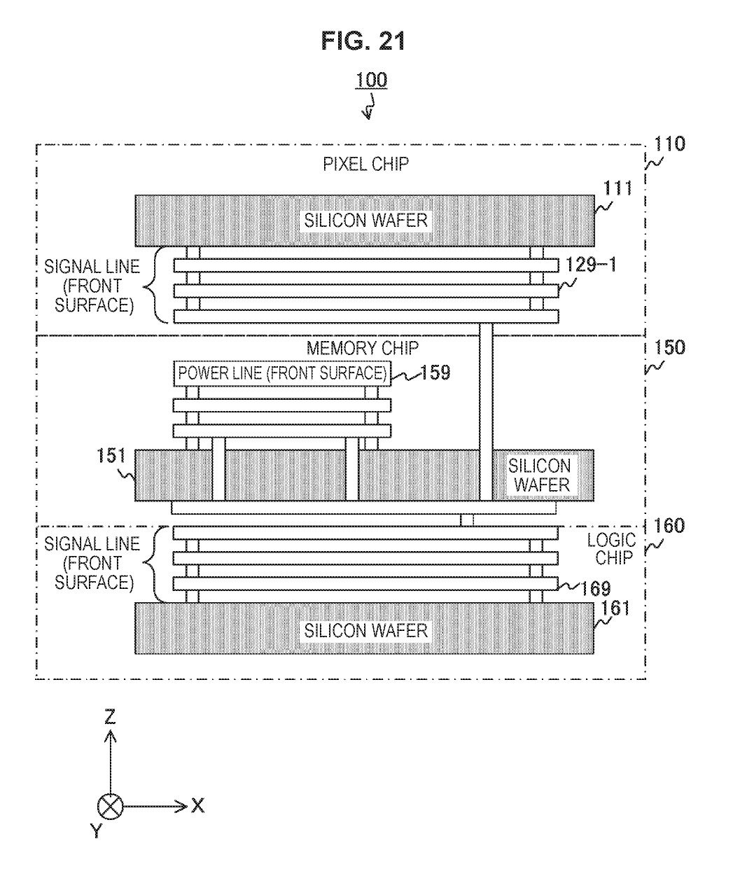

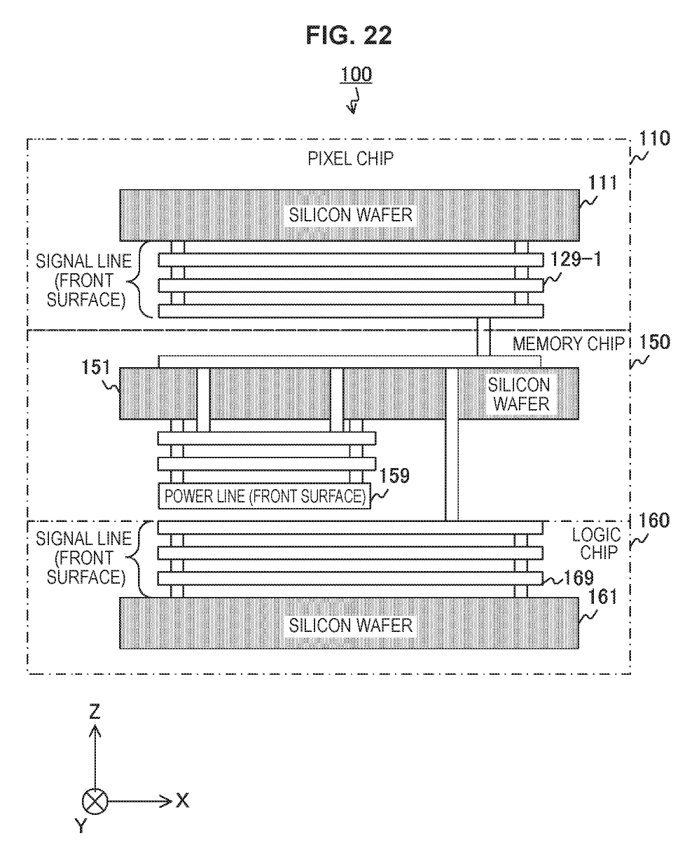

Moreover, as illustrated in FIG. 21, the silicon wafer 151 may be arranged so that its front surface faces upward, and the power line 159 or the like may be wired on the front surface thereof. Alternatively, as illustrated in FIG. 22, the silicon wafer 151 may be arranged so that its front surface faces downward, and the power line 159 or the like may be wired on the front surface thereof. In a case where the front surface of the silicon wafer 151 faces upward to increase the distance to the victim (the pixel array 130), it is preferable to wire the power line 159 or the like on the back surface thereof. In a case where the front surface faces downward, it is preferable to wire the power line 159 or the like on the front surface thereof.

In this manner, according to the eighth modification of the first embodiment of the present technology, the silicon wafer 151 is arranged so that its front surface faces upward, and the power line 159 or the ground line 158 is arranged on the back surface of the silicon wafer 151. Thus, it is possible to reduce electromagnetic noise even in the case where the front surface faces upward.

The above-described embodiments are examples for embodying the present technology, and matters in the embodiments each have a corresponding relationship with disclosure-specific matters in the claims. Likewise, the matters in the embodiments and the disclosure-specific matters in the claims denoted by the same names have a corresponding relationship with each other. However, the present technology is not limited to the embodiments, and various modifications of the embodiments may be embodied in the scope of the present technology without departing from the spirit of the present technology.

Note that effects described herein are not necessarily limitative, and any effect described in the present disclosure may be admitted.

Additionally, the present technology may also be configured as below.

(1)

A semiconductor device including:

a first substrate having a plurality of first signal lines wired on the first substrate in a predetermined direction; and

a second substrate having a second signal line wired on the second substrate, the second signal line being configured to produce a plurality of magnetic fields with mutually different directions in a region between two adjacent signal lines among the plurality of first signal lines.

(2)

The semiconductor device according to (1), in which the plurality of first signal lines are wired in parallel to each of two directions orthogonal to each other.

(3)

The semiconductor device according to (2), in which the second signal line is wired along a specific direction different from any of the two directions.

(4)

The semiconductor device according to (3),

in which the second signal line has a part wired along the specific direction and a remaining part wired along at least one of the two directions.

(5)

The semiconductor device according to (2),

in which the second signal line is wired along each of a plurality of directions different from any of the two directions.

(6)

The semiconductor device according to (1),

in which the second signal line is wired along a path bending at a plurality of bending points.

(7)

The semiconductor device according to any of (1) to (6),

in which the second substrate has a predetermined number of the second signal lines wired on the second substrate, and

an electric current flows through the two adjacent second signal lines in mutually different directions.

(8)

The semiconductor device according to any of (1) to (7),

in which the second substrate has both surfaces, one surface of the both surfaces having a circuit arranged on the one surface together with the second signal line.

(9)

The semiconductor device according to any of (1) to (7), in which the second substrate has both surfaces, one surface of the both surfaces having a circuit arranged on the one surface, the other surface having the second signal line wired on the other surface.

(10)

The semiconductor device according to any of (1) to (9),

in which the second signal line is a power line.

(11)

The semiconductor device according to any of (1) to (10),

in which the second substrate is further provided with dynamic random access memory (DRAM).

(12)

The semiconductor device according to any of (1) to (11),

in which the first substrate is further provided with a pixel circuit configured to convert light photoelectrically to generate a pixel signal.

(13)

The semiconductor device according to (12), further including:

a third substrate provided with a signal processing circuit configured to perform predetermined signal processing on the pixel signal.

(14)

A semiconductor device including:

a first substrate having a plurality of first signal lines wired on the first substrate in a predetermined direction; and

a second substrate having a second signal line wired on the second substrate along a path passing through both ends of a predetermined line segment parallel to a direction different from the predetermined direction and through an intermediate point different from any of the both ends of the predetermined line segment.

### REFERENCE SIGNS LIST

100 image sensor
110 pixel chip
111, 151, 161 silicon wafer
120 scanning circuit
130 pixel array
131 pixel circuit
150 memory chip
152 memory
160 logic chip
162 pre-processing unit
163 post-processing unit
164 interface

1. A semiconductor device comprising:
a first substrate having a plurality of first signal lines wired on the first substrate in a predetermined direction; and
a second substrate having a second signal line wired on the second substrate, the second signal line being configured to produce a plurality of magnetic fields with mutually different directions in a region between two adjacent signal lines among the plurality of first signal lines.

2. The semiconductor device according to claim 1,
wherein the plurality of first signal lines are wired in parallel to each of two directions orthogonal to each other.

3. The semiconductor device according to claim 2,
wherein the second signal line is wired along a specific direction different from any of the two directions.

4. The semiconductor device according to claim 3,
wherein the second signal line has a part wired along the specific direction and a remaining part wired along at least one of the two directions.

5. The semiconductor device according to claim 2,
wherein the second signal line is wired along each of a plurality of directions different from any of the two directions.

6. The semiconductor device according to claim 1,
wherein the second signal line is wired along a path bending at a plurality of bending points.

7. The semiconductor device according to claim 1,
wherein the second substrate has a predetermined number of the second signal lines wired on the second substrate, and
an electric current flows through the two adjacent second signal lines in mutually different directions.

8. The semiconductor device according to claim 1,
wherein the second substrate has both surfaces, one surface of the both surfaces having a circuit arranged on the one surface together with the second signal line.

9. The semiconductor device according to claim 1,
wherein the second substrate has both surfaces, one surface of the both surfaces having a circuit arranged on the one surface, the other surface having the second signal line wired on the other surface.

10. The semiconductor device according to claim 1,
wherein the second signal line is a power line.

11. The semiconductor device according to claim 1,
wherein the second substrate is further provided with dynamic random access memory (DRAM).

12. The semiconductor device according to claim 1,
wherein the first substrate is further provided with a pixel circuit configured to convert light photoelectrically to generate a pixel signal.

13. The semiconductor device according to claim 12, further comprising:
a third substrate provided with a signal processing circuit configured to perform predetermined signal processing on the pixel signal.

14. A semiconductor device comprising:
a first substrate having a plurality of first signal lines wired on the first substrate in a predetermined direction; and
a second substrate having a second signal line wired on the second substrate along a path passing through both ends of a predetermined line segment parallel to a direction different from the predetermined direction and through an intermediate point different from any of the both ends of the predetermined line segment.
